(19) United States
(12) Patent Application Publication
(10) Pub. No.: US 2015/0083468 A1
(43) Pub. Date: Mar. 26, 2015

(54) TEXTURED GLASS SUBSTRATE HAVING ENHANCED OPTICAL PROPERTIES FOR AN OPTOELECTRONIC DEVICE

(71) Applicant: AGC GLASS EUROPE, Louvain-La-Neuve (BE)

(72) Inventors: Benoit Domercq, Braine-l'Alleud (BE); Fabrice Sinapi, Spy (BE)

(73) Assignee: AGC GLASS EUROPE, Louvain-La-Neuve (BE)

(21) Appl. No.: 14/398,826

(22) PCT Filed: May 29, 2013
(86) PCT No.: PCT/EP2013/061109

§ 371 Date: Nov. 4, 2014

(30) Foreign Application Priority Data
May 29, 2012 (BE) 2012/0359

(51) Int. Cl. H05K 1/02; H05K 3/00; H05K 3/46; H05K 1/03

(52) U.S. Cl. CPC H05K 1/0274; H05K 1/0306; H05K 3/002; H05K 3/467; H05K 2201/0326
USPC 174/255; 216/24

(57) ABSTRACT

The invention relates to a glass substrate having enhanced optical properties for optoelectronic devices, wherein said substrate is totally or partially textured, by means of a chemical attack, on at least one of the surfaces thereof with a set of geometric patterns such that the arctangent of the ratio of the mean height of the patterns, R_{z}, to half the mean distance between the peaks of two contiguous patterns, R_{Sm}, is at least equal to an angle of 35° and at most equal to an angle of 80°.

### 1. FIELD OF THE INVENTION

The field of the invention is that of the technical field of textured glass substrates for an optoelectronic device.

More specifically, the invention relates to a textured glass substrate having improved optical properties for an optoelectronic device and to a process for the manufacture of such a textured glass substrate. Optoelectronic device is understood to mean any type of device which can emit or collect light. Such devices are, for example, organic light-emitting devices (OLEDs) or else light-collecting devices, such as organic photovoltaic cells, also known as solar cells. In particular, the invention relates to a glass substrate having improved optical properties for an organic light-emitting device (OLED).

The term textured is intended to denote the fact that the substrate comprises a texturing on at least one of its surfaces. Texturing is understood to mean a plurality of patterns creating a relief which are concave or convex with respect to the general plane of the face of the glass substrate. Both faces of the glass substrate may exhibit such patterns. By virtue of its texturing, the glass substrate exhibits improved optical properties. The term “improved optical properties” is intended to denote an improved transmittance of light, in other words an increase in the amount of light transmitted through the textured glass substrate. Thus, when the glass substrate is incorporated in an organic light-emitting device, an increase in the amount of light emitted by said organic light-emitting device is observed, whatever the orientation of the incident light, but also, more specifically, a reduction in the angular dependence of the purity of the color transmitted and also of the dominant wavelength of a color stimulus are observed.

The purity of the color is defined in the CIE 1931 XYZ colorimetric space by the Euclidian distance between the position of the color (x,y) and the white point (x_{I},y_{I}) on the plane of projection xy of the CIE, divided by the distance (still Euclidian) for a pure color (monochromatic or dichromatic in the same line) of the same hue (x_{P},y_{P})=ρₘₐₓ (x−x_{I}, y−y_{I})+(x_{I}, y_{I}):

$$p = \sqrt{\frac{{( x - {x}_{I} )}^{2} + {( y - {y}_{I} )}^{2}}{{( x - {x}_{P} )}^{2} + {( y - {y}_{P} )}^{2}}}$$

and ρₘₐₓ maximum within the limits of the chromatic diagram.

The dominant wavelength is the monochromatic wavelength which, mixed with an achromatic color, restores an equivalent colored impression.

### 2. SOLUTIONS OF THE PRIOR ART

It is known that a texturing of the surface of a substrate results in an increase in the amount of light transmitted. Thus, the document EP 1 449 017 B1 describes a glass plate textured by rolling which exhibits, on at least one of its faces, a plurality of patterns of pyramidal type. The surface thus obtained exhibits a better light transmittance. However, this is a process which requires relatively inflexible processing. This is because the texturing of the glass results from the impression of a pattern by producing an imprint by rolling the glass at its deformation temperature. Any modification to the texturing can be produced only by changing the imprint produced, which involves a change in the rolling roll used. This operation is lengthy and tedious. Furthermore, the roll used also tends to wear with time, which results in a problem of reproducibility of the imprint produced.

JP2004342523 describes an OLED having a transparent substrate, the surface of which opposite the organic system exhibits an uneven surface created by photolithography. The roughness is characterized therein with mean angles of between 5.7° and 31°, which represents angles which are too low to obtain good extraction of the light and a good reduction in the angular dependence of the dominant wavelength and of the purity of the color emitted by an organic light-emitting device.

### 3. OBJECTIVES OF THE INVENTION

An objective of the invention is in particular to overcome these disadvantages of the prior art.

More specifically, an objective of the invention, in at least one of its embodiments, is to provide a textured glass substrate for an optoelectronic device which exhibits improved light transmittance properties, whatever the orientation of the incident light. More specifically, it concerns providing a textured glass substrate which makes it possible to obtain an increase in the amount of light transmitted by an organic light-emitting device incorporating it, for polychromatic radiation covering a wavelength range.

Another objective of the invention, in at least one of its embodiments, is to provide a textured glass substrate which makes it possible to reduce the angular dependence of the dominant wavelength and of the purity of the color emitted by an organic light-emitting device incorporating said textured glass substrate.

The invention, in at least one of its embodiments, has the further objective of providing a textured glass substrate equipped with a transparent electrode. More particularly, it concerns providing a textured glass substrate equipped with an electrode comprising at least one metal layer, preferably made of silver.

### 4. DESCRIPTION OF THE INVENTION

In accordance with a specific embodiment, the invention relates to a glass substrate having improved optical properties for optoelectronic devices such that said substrate is textured, by chemical attack, completely or partially on at least one of its faces by a set of geometric patterns, such that:
the arctangent of the ratio of the mean height of the patterns, R_{z}, to half the mean distance separating the summits of two contiguous patterns, R_{Sm}, is at least equal to an angle of 35°,
the arctangent of the ratio of the height of the patterns, R_{z}, to half the distance separating the summits of two contiguous patterns, R_{Sm}, is at most equal to an angle of 80°.

The general principle of the invention is based on the texturing by chemical attack of a glass substrate, it being possible for this texturing to be carried out on at least one face of said substrate. The texturing can be carried out over the whole of the face or else over a portion of the latter. This texturing by chemical attack results in the formation of a set of geometric patterns such that their presence improves the optical properties of the glass substrate.

Thus, the invention is based on an entirely novel and inventive approach based on a chemical texturing of the glass substrate. This chemical texturing of the glass makes it possible to dispense with the stage of impression of a pattern by producing an imprint by rolling the glass brought to its deformation temperature and to be freed from the constraints related to this operation. This is because this form of texturing is more flexible and more easily controllable. More flexible method of texturing is understood to mean that the texturing of the surface, measured in the form of the roughness parameters R_{z} and R_{Sm}, can be modified by slight modifications to the attack times or to the chemical compositions of the attack solutions. More easily controllable method of texturing is understood to mean that the control of the texturing is related simply to the control of the composition of the attack solutions and of the attack times, this control being easier than control of the wear of a rolling roll which makes possible the impression of a pattern.

The term “textured” is understood to mean, in addition, that the glass substrate comprises at least one texturing of the surface by chemical attack, this texturing comprising at least frosting and/or etching, preferably frosting.

The chemical attack on the glass substrate can be carried out by acidic or alkaline chemical attack. The alkaline chemical attack on the substrate is carried out by bringing the surface of the substrate into contact with at least one alkaline chemical compound (NaOH, KOH or their mixture) applied in the solid form or in the form of a concentrated solution comprising at least 10% by weight of alkali. The substrate is brought, prior or subsequent to the application of the alkaline compound, to a temperature at least equal to 350° C.

The chemical attack on the glass substrate can advantageously be carried out by a controlled acidic attack, using acid solutions used in the manufacture of textured glass (for example by attack using hydrofluoric acid). Generally, the acid solutions are aqueous hydrofluoric acid solutions having a pH ranging from 0 to 5. Such aqueous solutions can comprise, in addition to the hydrofluoric acid, salts of this acid, other acids, such as, for example, hydrochloric acid, sulfuric acid, nitric acid, phosphoric acid and their salts (for example: Na₂SO₄, K₂SO₄, (NH₄)₂SO₄, BaSO₄, and the like), and optional additives in minor proportions (for example: acid/base buffering agents, wetting agents, and the like). The alkali metal salts and the ammonium salts are generally preferred; mention may very particularly be made, among these, of sodium, potassium and ammonium hydrofluoride and/or ammonium bifluoride. Such solutions are, for example, aqueous solutions comprising from 0 to 600 g/l of hydrofluoric acid, preferably from 150 to 250 g/l of hydrofluoric acid, and also comprising from 0 to 700 g/l of NH₄HF₂, preferably from 150 to 300 g/l of NH₄HF₂. The acidic attack can be carried out in one or more stages. The attack times are at least 10 s. Preferably, the attack times are at least 20 seconds. The attack times do not exceed 30 minutes. Mean height of the patterns, R_{z} defines the mean distance between the summit and the base of the patterns. The term “summit” is intended to denote the furthest point with respect to the base of the patterns. This point is unique in the case of a peak but it may be multiple when the summit exists in the form of a plateau. In the case of a summit existing in the form of a plateau, the distance R_{Sm} is the distance separating the middle points of said plates.

According to a specific form of the preceding form, the glass substrate is such that:
the arctangent of the ratio of the mean height of the patterns, R_{z}, to half the mean distance separating the summits of two contiguous patterns, R_{Sm}, is at least equal to an angle of 35°,
the arctangent of the ratio of the height of the patterns, R_{z}, to half the distance separating the summits of two contiguous patterns, R_{Sm}, is at most equal to an angle of 70°.

According to a specific form of the preceding form, the glass substrate is such that:
the arctangent of the ratio of the mean height of the patterns, R_{z}, to half the mean distance separating the summits of two contiguous patterns, R_{Sm}, is at least equal to an angle of 35°,
the arctangent of the ratio of the height of the patterns, R_{z}, to half the distance separating the summits of two contiguous patterns, R_{Sm}, is at most equal to an angle of 60°.

The arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, most preferably having a value within the range extending from 35° to 60°.

According to a specific embodiment of the preceding form, the glass substrate according to the invention comprises at least one complete or partial texturing of the surface of the substrate opposite the surface intended to receive the optoelectronic device.

According to a specific embodiment of the preceding form, the texturing of the surface comprises at least the formation of pyramids having a polygonal base, the smallest angle of which formed between, on the one hand, the plane parallel to the base of said pyramids and, on the other hand, the plane of at least one side face of said pyramids is at least 35°. The angle formed between, on the one hand, a plane parallel to the base of said pyramids and, on the other hand, the plane of at least one side face of said pyramids is at most 80°, preferably at most 70°, more preferably at most 60°. The angle formed between, on the one hand, a plane parallel to the base of said pyramids and, on the other hand, the plane of at least one side face of said pyramids is within the range of values extending from 35° to 80°, preferably within the range of values extending from 35° to 70°, more preferably within the range of values extending from 35° to 60°. The advantage offered by the partial or complete texturing of the surface of the substrate is that it makes it possible to reduce the losses related to the internal reflections at the interfaces of this substrate. According to a specific embodiment, the glass substrate has a refractive index at least equal to 1.5. The use of a substrate having a higher refractive index makes it possible to obtain, with the same optoelectronic system and the same texturing, a greater amount of transmitted light and thus a greater brightness.

The glass substrate is advantageously chosen in particular from the glass Matelux Clear from AGC, the glass Matelux Light from AGC, the glass Matelux Double Sided from AGC, the glass Matelux Clearvision from AGC, the glass Matelux Antislip from AGC, the glass Arctic White from AGC, the glass Matelux Stopsol Supersilver Clear from AGC, the glass Glamatt from AGC, the glass Matobel from AGC, and the like.

According to a specific embodiment, the substrate is such that the geometric patterns comprise at least one structure of step pyramid type having a polygonal base. The term “step pyramid” is understood to mean a pyramid, at least one face of which exhibits a staircase structure. This staircase structure is such that the dimensions of the steps and of the risers are not necessarily equal to one another and paired. The angle formed by a plane comprising a step and a plane comprising a riser is not necessarily equal to 90°. Preferably, the “step-riser” angle seen from the inside of the pyramid is at least 100°, more preferably at least 120°, most preferably at least 145°. This angle can vary from one “step-riser” structure to another.

Preferably, the geometric patterns are as close as possible to one another. According to a preferred embodiment, the substrate comprises joined patterns. Joined patterns defines two patterns which touch in at least a portion of their base. Joined patterns make it possible to obtain a surface of the substrate exhibiting a greater pattern density, thereby a greater texturing and thus an even greater transmittance of light.

According to a preferred embodiment, the substrate comprises patterns which are completely joined. Pattern which is completely joined is understood to mean that every side of the base of a pattern also forms part of the base of another pattern.

Another subject matter of the invention is a textured glass substrate such that it comprises, on at least one of its faces, at least one transparent electrode. The electrode included in the substrate of the present invention will be regarded as transparent when it exhibits a light absorption of at most 50%, indeed even at most 30%, preferably at most 20%, more preferably at most 10%, in the range of wavelengths of visible light. In addition, the electrode included in the glass substrate according to the invention can behave as an anode or, on the contrary, as a cathode, according to the type of device in which it is inserted.

According to a preferred embodiment, the textured glass substrate according to the invention is such that said substrate is completely or partially textured on the face of the substrate opposite the face on which said transparent electrode is deposited, it being possible for the face of the substrate on the transparent electrode side to be or not to be textured; preferably, the face on the transparent electrode side is not textured.

According to a specific embodiment of the preceding form, the textured glass substrate for optoelectronic devices is such that the transparent electrode comprises at least one layer of conducting oxide based on at least one doped oxide, preferably selected from tin-doped indium oxide (ITO), zinc oxide doped by at least one doping element selected from aluminum (AZO) or gallium (GZO), or tin oxide doped with fluorine or with antimony.

According to another embodiment, the textured glass substrate for optoelectronic devices is such that the transparent electrode comprises a stack comprising at least one conducting metal layer, preferably just one conducting metal layer, and at least one coating endowed with properties for improving the transmittance of light through said electrode, said coating having a geometric thickness at least greater than 3.0 nm and at most less than or equal to 200 nm, preferably less than or equal to 170 nm, more preferably less than or equal to 130 nm, said coating comprising at least one layer for improving the transmittance of light and being located between the conducting metal layer and the substrate on which said electrode is deposited.

According to a specific embodiment of the preceding form, the textured glass substrate for optoelectronic devices is such that the transparent electrode comprises a stack comprising just one conducting metal layer and at least one coating endowed with properties for improving the transmittance of light through said electrode, said coating having a geometric thickness at least greater than 3.0 nm and at most less than or equal to 200 nm, preferably less than or equal to 170 nm, more preferably less than or equal to 130 nm, said coating comprising at least one layer for improving the transmittance of light and being located between the conducting metal layer and the substrate on which said electrode is deposited, such that the optical thickness of the coating endowed with properties for improving the transmittance of the light, T_{D1}, and the geometric thickness of the conducting metal layer, T_{ME}, are connected by the relationship:

T_{ME}=T_{ME}_{_{—}}₀+[B*sin(Π*T_{D1}/T_{D1}_{_{—}}₀)]/(n_{substrate})³

where T_{ME}_{_{—}}₀, B and T_{D1}_{_{—}}₀ are constants with T_{ME}_{_{—}}₀ having a value within the range extending from 10.0 to 25.0 nm, B having a value within the range extending from 10.0 to 16.5 and T_{D1}_{_{—}}₀ having a value within the range extending from 23.9*n_{D1} to 28.3*n_{D1} nm with n_{D1} representing the refractive index of the coating for improving the transmittance of the light at a wavelength of 550 nm, and n_{substrate} represents the refractive index of the glass constituting the substrate at a wavelength of 550 nm. Preferably, the constants T_{ME}_{_{—}}₀, B and T_{D1}_{_{—}}₀ are such that T_{ME}_{_{—}}₀ has a value within the range extending from 11.5 to 22.5 nm, B has a value within the range extending from 12 to 15 and T_{D1}_{_{—}}₀ has a value within the range extending from 24.8*n_{D1} to 27.3*n_{D1} nm. More preferably, the constants T_{ME}_{_{—}}₀, B and T_{D1}_{_{—}}₀ are such that T_{ME}_{_{—}}₀ has a value within the range extending from 12.0 to 22.5 nm, B has a value within the range extending from 12 to 15 and T_{D1}_{_{—}}₀ has a value within the range extending from 24.8*n_{D1} to 27.3*n_{D1} nm.

The advantage offered by the substrate according to the invention is that it makes it possible to obtain an increase in the amount of light emitted or converted by an optoelectronic device incorporating it, for a monochrome radiation, more particularly in the amount of light emitted in the case of an organic light-emitting device (OLED).

The term “a coating endowed with properties for improving the transmittance of light” is intended to denote a coating, the presence of which in the stack constituting the electrode results in an increase in the amount of light transmitted through the substrate, for example a coating having antireflective properties. In other words, an optoelectronic device incorporating the substrate according to the invention emits or converts a greater amount of light in comparison with an optoelectronic device of the same nature but comprising a conventional electrode (for example: ITO) deposited on a substrate identical to the substrate according to the invention. More particularly, when the substrate is inserted into an organic light-emitting device, the increase in the amount of light emitted is characterized by a greater brightness value, whatever the color of the light emitted.

The geometric thickness of the coating for improving the transmittance of light has to have a thickness at least greater than 3 nm, preferably at least equal to 5 nm, more preferably at least equal to 7 nm, most preferably at least equal to 10 nm. For example, when the coating for improving the transmittance of light is based on zinc oxide, on zinc oxide substoichiometric in oxygen, ZnOₓ, these zinc oxides optionally being doped or alloyed with tin, a geometric thickness of the coating for improving the transmittance of the light at least greater than 3 nm makes it possible to obtain a conducting metal layer, in particular made of silver, exhibiting a good conductivity. The geometric thickness of the coating for improving the transmittance of the light advantageously has a thickness of less than or equal to 200 nm, preferably of less than or equal to 170 nm, more preferably of less than or equal to 130 nm, the advantage offered by such thicknesses residing in the fact that the process for the manufacture of said coating is faster.

The term “substrate” is also intended to denote not only the glass substrate as such but also any structure comprising the glass substrate and also at least one layer of a material having a refractive index, nₘₐₜₑᵣᵢₐₗ, close to the refractive index of the glass constituting the substrate, n_{substrate}, in other words |n_{substrate}−nₘₐₜₑᵣᵢₐₗ|≦0.1. |n_{substrate}−nₘₐₜₑᵣᵢₐₗ| represents the absolute value of the difference between the refractive indices. Mention may be made, as example, of a layer of silicon oxide deposited on a glass substrate made of soda-lime-silica glass.

The glass substrate preferably has a geometric thickness of at least 0.35 nm. The term “geometric thickness” is understood to mean the mean geometric thickness. The glasses are inorganic or organic. Inorganic glasses are preferred. Preference is given, among these, to soda-lime-silica glasses which are clear or colored in their body or at the surface. More preferably, these are extra clear soda-lime-silica glasses. The term extra clear denotes a glass comprising at most 0.020% by weight of the glass of total Fe, expressed as Fe₂O₃, and preferably at most 0.015% by weight. For cost reasons, the refractive index of the glass, n_{substrate}, preferably has a value of between 1.4 and 1.6. More preferably, the refractive index of the glass has a value equal to 1.5. n_{substrate} represents the refractive index of the glass constituting the substrate at a wavelength of 550 nm.

According to a specific embodiment, the glass substrate according to the invention is such that the glass which constitutes it has a refractive index of between 1.4 and 1.6 at a wavelength of 550 nm and that the electrode which it comprises is such that the optical thickness of the coating endowed with properties for improving the transmittance of the light, T_{D1}, and the geometric thickness of the conducting metal layer, T_{ME}, are connected by the relationship:

T_{ME}=T_{ME}_{_{—}}₀+[B*sin(Π*T_{D1}/T_{D1}_{_{—}}₀)]/(n_{substrate})³

where T_{ME}_{_{—}}₀, B and T_{D1}_{_{—}}₀ are constants with T_{ME}_{_{—}}₀ having a value within the range extending from 10.0 to 25.0 nm, preferably from 10.0 to 23.0 nm, B having a value within the range extending from 10.0 to 16.5 and T_{D1}_{_{—}}₀ having a value within the range extending from 23.9*n_{D1} to 28.3*n_{D1} nm with n_{D1} representing the refractive index of the coating for improving the transmittance of the light at a wavelength of 550 nm, and n_{substrate} represents the refractive index of the glass constituting the substrate at a wavelength of 550 nm. Preferably, the constants T_{ME}_{_{—}}₀, B and T_{D1}_{_{—}}₀ are such that T_{ME}_{_{—}}₀ has a value within the range extending from 10.0 to 23.0 nm, preferably from 10.0 to 22.5 nm, most preferably from 11.5 to 22.5 nm, B has a value within the range extending from 11.5 to 15.0 and T_{D1}_{_{—}}₀ has a value within the range extending from 24.8*n_{D1} to 27.3*n_{D1} nm. More preferably, the constants T_{ME}_{_{—}}₀, B and T_{D1}_{_{—}}₀ are such that T_{ME}_{_{—}}₀ has a value within the range extending from 10.0 to 23.0 nm, preferably from 10.0 to 22.5 nm, most preferably from 11.5 to 22.5 nm, B has a value within the range extending from 12.0 to 15.0 and T_{D1}_{_{—}}₀ has a value within the range extending from 24.8*n_{D1} to 27.3*n_{D1} nm.

According to a specific embodiment, the glass substrate according to the invention is such that the glass which constitutes it has a refractive index equal to 1.5 at a wavelength of 550 nm and that the electrode which it comprises is such that the optical thickness of the coating endowed with properties for improving the transmittance of the light, T_{D1}, and the geometric thickness of the conducting metal layer, T_{ME}, are connected by the relationship:

T_{ME}=T_{ME}_{_{—}}₀+[B*sin(Π*T_{D1}/T_{D1}_{_{—}}₀)]/(n_{substrate})³

where T_{ME}_{_{—}}₀, B and T_{D1}_{_{—}}₀ are constants with T_{ME}_{_{—}}₀ having a value within the range extending from 10.0 to 25.0 nm, preferably from 10.0 to 23.0 nm, B having a value within the range extending from 10.0 to 16.5 and T_{D1}_{_{—}}₀ having a value within the range extending from 23.9*n_{D1} to 27.3*n_{D1} nm with n_{D1} representing the refractive index of the coating for improving the transmittance of the light at a wavelength of 550 nm, and n_{substrate} represents the refractive index of the glass constituting the substrate at a wavelength of 550 nm. Preferably, the constants T_{ME}_{_{—}}₀, B and T_{D1}_{_{—}}₀ are such that T_{ME}_{_{—}}₀ has a value within the range extending from 10.0 to 23.0 nm, preferably from 10 to 22.5 nm, most preferably from 11.5 to 22.5 nm, B has a value within the range extending from 11.5 to 15.0 and T_{D1}_{_{—}}₀ has a value within the range extending from 24.8*n_{D1} to 27.3*n_{D1} nm. More preferably, the constants T_{ME}_{_{—}}₀, B and T_{D1}_{_{—}}₀ are such that T_{ME}_{_{—}}₀ has a value within the range extending from 10.0 to 23.0 nm, preferably from 10 to 22.5 nm, most preferably from 11.5 to 22.5 nm, B has a value within the range extending from 12.0 to 15.0 and T_{D1}_{_{—}}₀ has a value within the range extending from 24.8*n_{D1} to 27.3*n_{D1} nm.

According to a specific embodiment of the preceding form, the glass substrate according to the invention is such that the geometric thickness of the conducting metal layer is at least equal to 6.0 nm, preferably at least equal to 8.0 nm, more preferably at least equal to 10.0 nm and at most equal to 22.0 nm, preferably at most equal to 20.0 nm, more preferably at most equal to 18.0 nm, and the geometric thickness of the coating for improving the transmittance of light of which is at least equal to 50.0 nm, preferably at least equal to 60.0 nm, and at most equal to 130.0 nm, preferably at most equal to 110.0 nm, more preferably at most equal to 90.0 nm.

According to a specific embodiment, the glass substrate according to the invention is such that the glass which constitutes it has a refractive index value within the range extending from 1.4 to 1.6 and is such that the geometric thickness of the conducting metal layer is at least equal to 16.0 nm, preferably at least equal to 18.0 nm, more preferably at least equal to 20.0 nm, and at most equal to 29.0 nm, preferably at most equal to 27.0 nm, more preferably at most equal to 25.0 nm, and the geometric thickness of the coating for improving the transmittance of light of which is at least equal to 20.0 nm and at most equal to 40.0 nm. Surprisingly, the use of a thick conducting metal layer in combination with an optimized thickness of the coating for improving the transmittance of light makes it possible to obtain optoelectronic systems, more particularly OLED devices, having, on the one hand, a high brightness and, on the other hand, incorporating a glass substrate, the electrode of which has a lower surface resistance, expressed in Ω/□.

According to a preferred embodiment, the glass substrate according to the invention is such that the refractive index of the material constituting the coating for improving the transmittance of the light (n_{D1}) is greater than the refractive index of the glass constituting the substrate (n_{substrate}) (n_{D1}>n_{substrate}), preferably n_{D1}>1.2*n_{substrate}, more preferably n_{D1}>1.3*n_{substrate}, most preferably n_{D1>}1.5*n_{substrate}. The refractive index of the material constituting the coating (n_{D1}) has a value ranging from 1.5 to 2.4, preferably ranging from 2.0 to 2.4, more preferably ranging from 2.1 to 2.4, at a wavelength of 550 nm. When the coating for improving the transmittance of light is composed of several layers, n_{D1} is given by the relationship:

$${n}_{D 1} = \frac{{\sum }_{x = 1}^{m} {n}_{x} \times {l}_{x}}{{l}_{D 1}}$$

where m represents the number of layers constituting the coating, nₓ represents the refractive index of the material constituting the x^{th} layer starting from the substrate, lₓ represents the geometric thickness of the x^{th} layer and l_{D1} represents the geometric thickness of the coating. The use of a material having a higher refractive index makes it possible to obtain a greater amount of light emitted or transmitted. The advantage offered increases as the difference between the refractive index of the coating for improving the transmittance of light and the refractive index of the glass constituting the substrate increases.

The material constituting at least one layer of the coating for improving the transmittance of light comprises at least one dielectric compound and/or at least one electrically conducting compound. The term “dielectric compound” is intended to denote at least one compound chosen from:
oxides of at least one element selected from Y, Ti, Zr, Hf, V, Nb, Ta, Cr, Mo, W, Ni, Zn, Al, Ga, In, Si, Ge, Sn, Sb, Bi, and the mixture of at least two of them;
nitrides of at least one element selected from boron, aluminum, silicon, germanium and their mixture;
silicon oxynitride, aluminum oxynitride;
a silicon oxycarbide.

When it is present, the dielectric compound preferably comprises an yttrium oxide, a titanium oxide, a zirconium oxide, a hafnium oxide, a niobium oxide, a tantalum oxide, a zinc oxide, a tin oxide, an aluminum oxide, an aluminum nitride, a silicon nitride and/or a silicon oxycarbide.

The term “conducting” is intended to denote at least one compound chosen from:
oxides which are substoichiometric in oxygen and oxides doped with at least one element selected from Ti, Zr, Hf, V, Nb, Ta, Cr, Mo, W, Zn, Al, Ga, In, Si, Ge, Sn, Sb, Bi and the mixture of at least two of them;
nitrides doped with at least one element selected from boron, aluminum, silicon, germanium and their mixture;
doped Si oxycarbide.

Preferably, the dopants comprise at least one of the elements chosen from Al, Ga, In, Sn, P, Sb and F. In the case of silicon oxynitride, the dopants comprise B, Al and/or Ga.

Preferably, the conducting compound comprises at least ITO and/or doped Sn oxide, the dopant being at least one element chosen from F and Sb, and/or doped Zn oxide, the dopant being at least one element chosen from Al, Ga, Sn and Ti. According to a preferred embodiment, the inorganic chemical compound comprises at least ZnOₓ (with x≦1) and/or ZnₓSn_{y}O_{z} (with x+y≧3 and z≦6). Preferably, the ZnₓSn_{y}O_{z} comprises at most 95% by weight of zinc; the percentage by weight of zinc is expressed with respect to the total weight of the metals present in the layer.

The conducting metal layer of the electrode constituting a portion of the glass substrate according to the invention mainly provides the electrical conduction of said electrode. It comprises at least one layer comprising a metal or a mixture of metals. The generic expression “mixture of metals” denotes the combinations of at least two metals in the alloy form or in the form of a doping of at least one metal by at least one other metal; the metal and/or the mixture of metals comprising at least one element selected from Pd, Pt, Cu, Ag, Au and Al. Preferably, the metal and/or the mixture of metals comprises at least one element selected from Cu, Ag, Au and Al. More preferably, the conducting metal layer comprises at least Ag in the pure form or alloyed with another metal. Preferably, the other metal comprises at least one element selected from Au, Pd, Al, Cu, Zn, Cd, In, Si, Zr, Mo, Ni, Cr, Mg, Mn, Co and Sn. More preferably, the other metal comprises at least Pd and/or Au, preferably Pd.

According to a specific embodiment, the coating for improving the transmittance of light of the electrode constituting a portion of the substrate according to the invention comprises at least one additional crystallization layer, said crystallization layer being, with respect to the substrate, the outermost layer of the stack constituting said coating. This layer makes possible preferential growth of the metal layer, for example silver layer, constituting the conducting metal layer and makes it possible to obtain, for this reason, good electrical and optical properties of the conducting metal layer. It comprises at least one inorganic chemical compound. The inorganic chemical compound constituting the crystallization layer does not necessarily have a high refractive index. The inorganic chemical compound comprises at least ZnO (with x≦1) and/or ZnₓSn_{y}O_{z} (with x+y≧3 and z≦6). Preferably, the ZnₓSn_{y}O_{z} comprises at most 95% by weight of zinc; the percentage by weight of zinc is expressed with respect to the total weight of metals present in the layer. Preferably, the crystallization layer is made of ZnO. As the layer endowed with the property of improving the transmittance of light has a thickness generally greater than that normally encountered in the field of conducting multilayer coatings (for example: coating of low emissivity type), the thickness of the crystallization layer has to be adjusted and increased in order to provide a conducting metal layer having good conduction and very little absorption.

According to a specific embodiment, the geometric thickness of the crystallization layer is at least equal to 7% of the total geometric thickness of the coating for improving the transmittance of the light, preferably to 11%, more preferably to 14%. For example, in the case of a coating for improving the transmittance of the light comprising a layer for improving the transmittance of light and a crystallization layer, the geometric thickness of the layer for improving the transmittance of light has to be reduced if the geometric thickness of the crystallization layer is increased, so as to observe the relationship between geometric thickness of the conducting metal layer and optical thickness of the coating for improving the transmittance of the light.

According to a specific embodiment, the crystallization layer is merged with at least one layer for improving the transmittance of light constituting the coating for improving the transmittance of light.

According to a specific embodiment, the coating for improving the transmittance of light of the transparent electrode comprises at least one additional barrier layer, said barrier layer being, with respect to the face of the substrate on which the electrode is deposited, the innermost layer of the stack constituting said coating. This layer makes possible in particular protection of the electrode against any contamination by migration of alkali metals coming from the glass substrate, for example made of soda-lime-silica glass, and thus an extension of the lifetime of the electrode. The barrier layer comprises at least one compound selected from:
titanium oxide, zirconium oxide, aluminum oxide, yttrium oxide and the mixture of at least two of them;
mixed zinc/tin, zinc/aluminum, zinc/titanium, zinc/indium and tin/indium oxide;
silicon nitride, silicon oxynitride, silicon oxycarbide, silicon oxycarbonitride, aluminum nitride, aluminum oxynitride and the mixture of at least two of them;
   this barrier layer optionally being doped or alloyed with tin.

According to a specific embodiment, the barrier layer is merged with at least one layer for improving the transmittance of light constituting the coating for improving the transmittance of light.

According to a preferred embodiment of the barrier and crystallization layers, at least one of these two additional layers is merged with at least one layer for improving the transmittance of light of the coating for improving the transmittance of light.

According to a specific embodiment, the glass substrate according to the invention is such that the electrode comprises a thin layer for rendering uniform the surface electrical properties located, with respect to the face of the substrate on which the electrode is deposited, at the summit of the multilayer stack constituting said electrode. The thin layer for rendering uniform the surface electrical properties has the main role of making it possible to obtain a uniform charge transfer over the entire surface of the electrode. This uniform transfer is reflected by an emitted or converted light flux which is equivalent at every point of the surface. It also makes it possible to increase the lifetime of the optoelectronic devices, given that this transfer is the same at each point, possible hotspots being eliminated in that way. The layer for rendering uniform has a geometric thickness of at least 0.5 nm, preferably at least 1.0 nm. The layer for rendering uniform has a geometric thickness of at most 6.0 nm, preferably of at most 2.5 nm, most preferably of at most 2.0 nm. More preferably, the layer for rendering uniform is equal to 1.5 nm. The layer for rendering uniform comprises at least one layer comprising at least one inorganic material selected from a metal, a nitride, an oxide, a carbide, an oxynitride, an oxycarbide, a carbonitride or an oxycarbonitride.

According to a first specific embodiment of the preceding form, the inorganic material of the layer for rendering uniform comprises just one metal or a mixture of metals. The generic expression “mixture of metals” denotes the combinations of at least two metals in the alloy form or in the form of a doping of at least one metal by at least one other metal. The method for rendering uniform comprises at least one element selected from Li, Na, K, Be, Mg, Ca, Ba, Sc, Y, Ti, Zr, Hf, Ce, V, Nb, Ta, Cr, Mo, W, Mn, Fe, Ru, Co, Rh, Ir, Ni, Pd, Pt, Cu, Ag, Au, Zn, B, Al, Ga, In, Tl, C, Si, Ge, Sn and Pb. The metal and/or the mixture of metals comprises at least one element selected from Li, Na, K, Mg, Ca, Ti, Zr, Hf, V, Nb, Ta, Cr, Mo, W, Mn, Co, Ni, Pd, Pt, Cu, Ag, Au, Zn, Cd, Al, Si and C. More preferably, the metal or the mixture of metals comprises at least one element selected from C, Ti, Zr, Hf, V, Nb, Ta, Ni, Cr, Al and Zn. The mixture of metals preferably comprises Ni—Cr and/or Zn doped with Al. The advantage offered by this specific embodiment is that it makes it possible to obtain the best possible compromise between, on the one hand, the electrical properties resulting from the effect of the layer for rendering uniform the surface electrical properties and, on the other hand, the optical properties obtained by virtue of the coating for improving. The use of a layer for rendering uniform which has the lowest possible thickness is fundamental. This is because the influence of this layer on the amount of light emitted or converted by the optoelectronic device decreases as its thickness decreases. This layer for rendering uniform, when it is made of metal, thus differs from the conducting layer in its lower thickness, this thickness being insufficient to provide conductivity. Thus it is that the layer for rendering uniform, when it is made of metal, that is to say composed of just one metal or a mixture of metals, preferably has a geometric thickness of at most 5.0 nm.

According to a second specific embodiment, the inorganic material of the layer for rendering uniform is present in the form of at least one chemical compound selected from carbides, carbonitrides, oxynitrides, oxycarbides, oxycarbonitrides and the mixtures of at least two of them. The oxynitrides, oxycarbides and oxycarbonitrides of the layer for rendering uniform can be in a form which is nonstoichiometric, preferably substoichiometric, with respect to the oxygen. The carbides are carbides of at least one element selected from Be, Mg, Ca, Ba, Sc, Y, Ti, Zr, Hf, Ce, V, Nb, Ta, Cr, Mo, W, Mn, Fe, Co, Rh, Ir, Ni, Pd, Pt, Cu, Au, Zn, Cd, B, Al, Si, Ge, Sn and Pb, preferably of at least one element selected from Ti, Zr, Hf, V, Nb, Ta, Cr, Mo, W, Mn, Co, Ni, Pd, Pt, Cu, Au, Zn, Cd, Al and Si, more preferably of at least one element selected from Ti, Zr, Hf, V, Nb, Ta, Ni, Cr, Zn and Al. The carbonitrides are carbonitrides of at least one element selected from Be, Sc, Y, Ti, Zr, Hf, V, Nb, Cr, Mo, W, Fe, Co, Zn, B, Al and Si, preferably of at least one element selected from Ti, Zr, Hf, V, Nb, Ta, Cr, Mo, W, Co, Zn, Al and Si, more preferably of at least one element selected from Ti, Zr, Hf, V, Nb, Ta, Cr, Zn and Al. The oxynitrides are oxynitrides of at least one element selected from Be, Mg, Ca, Sr, Sc, Y, Ti, Zr, Hf, V, Nb, Ta, Cr, Mo, W, Mn, Fe, Co, Rh, Ir, Ni, Cu, Au, Zn, B, Al, Ga, In, Si and Ge, preferably of at least one element selected from Ti, Zr, Hf, V, Nb, Ta, Cr, Mo, W, Mn, Co, Ni, Cu, Au, Zn, Al and Si, more preferably of at least one element selected from Ti, Zr, Hf, V, Nb, Ta, Cr, Zn and Al. The oxycarbides are oxycarbides of at least one element selected from Be, Mg, Ca, Sr, Sc, Y, Ti, Zr, Hf, V, Nb, Cr, Mo, W, Mn, Fe, Ni, Zn, Si and Ge, preferably of at least one element selected from Ti, Zr, Hf, V, Nb, Cr, Mo, W, Mn, Ni, Zn, Al and Si, more preferably of at least one element selected from Ti, Zr, Hf, V, Nb, Cr, Zn and Al. The oxycarbonitrides are oxycarbonitrides of at least one element selected from Be, Ti, Zr, Hf, V, Nb, Cr, Mo, W, Mn, Zn, B, Al, Si and Ge, preferably of at least one element selected from Ti, Zr, Hf, V, Nb, Cr, Mo, W, Mn, Zn, Al and Si, more preferably of at least one element selected from Ti, Zr, Hf, V, Nb, Cr, Zn and Al. The carbides, carbonitrides, oxynitrides, oxycarbides and oxycarbonitrides of the layer for rendering uniform the surface electrical properties optionally comprise at least one doping element. In a preferred embodiment, the thin layer for rendering uniform comprises at least one oxynitride comprising at least one element selected from Ti, Zr, Cr, Mo, W, Mn, Co, Ni, Cu, Au, Zn, Al and Si. More preferably, the thin layer for rendering uniform the surface electrical properties comprises at least one oxynitride chosen from Ti oxynitride, Zr oxynitride, Ni oxynitride and NiCr oxynitride.

According to a third specific embodiment, the inorganic material of the layer for rendering uniform is present in the form of at least one metal nitride of at least one element selected from Be, Mg, Ca, Sr, Ba, Sc, Y, Ti, Zr, Hf, V, Nb, Ta, Cr, Mo, W, Mn, Fe, Ru, Os, Co, Rh, Ir, Ni, Pd, Pt, Cu, Ag, Au, Zn, Cd, B, Al, Ga, In, Si, Ge and Sn. Preferably, the layer for rendering uniform comprises at least one nitride of an element selected from Ti, Zr, Hf, V, Nb, Ta, Cr, Mo, W, Mn, Co, Ni, Pd, Pt, Cu, Ag, Au, Zn, Cd, Al and Si. More preferably, the nitride comprises at least one element selected from Ti, Zr, Hf, V, Nb, Ta, Ni, Cr, Al and Zn. More preferably, the thin layer for rendering uniform the surface electrical properties comprises at least Ti nitride, Zr nitride, Ni nitride or NiCr nitride.

According to a fourth specific embodiment, the inorganic material of the layer for rendering uniform is present in the form of at least one metal oxide of at least one element selected from Be, Mg, Ca, Sr, Ba, Sc, Y, Ti, Zr, Hf, V, Nb, Ta, Cr, Mo, W, Mn, Fe, Ru, Os, Co, Rh, Ir, Ni, Pd, Pt, Cu, Ag, Au, Zn, Cd, B, Al, Ga, In, Si, Ge, Sn and Pb. Preferably, the layer for rendering uniform comprises at least one oxide of an element selected from Ti, Zr, Hf, V, Nb, Ta, Cr, Mo, W, Mn, Co, Ni, Pd, Pt, Cu, Ag, Au, Zn, Cd, Al, In, Si and Sn. More preferably, the oxide comprises at least one element selected from Ti, Zr, Hf, V, Nb, Ta, Ni, Cu, Cr, Al, In, Sn and Zn. The oxide of the layer for rendering uniform can be an oxide which is substoichiometric in oxygen. The oxide optionally comprises at least one doping element. Preferably, the doping element is selected from at least one of the elements chosen from Al, Ga, In, Sn, Sb, F and Ag. More preferably, the thin layer for rendering uniform the surface electrical properties comprises at least doped Ti oxide and/or Zr oxide and/or Ni oxide and/or NiCr oxide and/or ITO and/or Cu oxide, the dopant being Ag, and/or doped Sn oxide, the dopant being at least one element chosen from F and Sb, and/or doped Zn oxide, the dopant being at least one element chosen from Al, Ga, Sn and Ti.

According to a specific embodiment, the glass substrate according to the invention is such that the electrode comprises at least one additional insertion layer located between the conducting metal layer and the thin layer for rendering uniform. The layer inserted between the conducting metal layer and the layer for rendering uniform comprises at least one layer comprising at least one dielectric compound and/or at least one electrically conducting compound. Preferably, the insertion layer comprises at least one layer comprising at least one conducting compound. The role of this insertion layer is to constitute a portion of an optical cavity which makes it possible to render the conducting metal layer transparent. The term “dielectric compound” is intended to denote at least one compound chosen from:
oxides of at least one element selected from Y, Ti, Zr, Hf, V, Nb, Ta, Cr, Mo, W, Zn, Al, Ga, In, Si, Ge, Sn, Sb, Bi, and the mixture of at least two of them,
nitrides of at least one element selected from boron, aluminum, silicon, germanium and their mixture,
silicon oxynitride, aluminum oxynitride,
a silicon oxycarbide.

When it is present, the dielectric compound preferably comprises an yttrium oxide, a titanium oxide, a zirconium oxide, a hafnium oxide, a niobium oxide, a tantalum oxide, a zinc oxide, a tin oxide, an aluminum oxide, an aluminum nitride, a silicon nitride and/or a silicon oxycarbide.

The term “conducting” is intended to denote at least one compound chosen from:
oxides which are substoichiometric in oxygen and oxides doped with at least one element selected from Y, Ti, Zr, Hf, V, Nb, Ta, Cr, Mo, W, Zn, Al, Ga, In, Si, Ge, Sn, Sb, Bi and the mixture of at least two of them,
nitrides doped with at least one element selected from boron, aluminum, silicon, germanium and their mixture,
doped Si oxycarbide.

Preferably, the dopants comprise at least one of the elements chosen from Al, Ga, In, Sn, P, Sb and F. In the case of silicon oxynitride, the dopants comprise B, Al and/or Ga.

Preferably, the conducting compound comprises at least ITO and/or doped Sn oxide, the dopant being at least one element chosen from F and Sb, and/or doped Zn oxide, the dopant being at least one element chosen from Al, Ga, Sn and Ti. According to a preferred embodiment, the inorganic chemical compound comprises at least ZnOₓ (with x≦1) and/or ZnₓSn_{y}O_{z} (with x+y≧3 and z≦6). Preferably, the ZnₓSn_{y}O_{z} comprises at most 95% by weight of zinc; the percentage by weight of zinc is expressed with respect to the total weight of the metals present in the layer.

According to a specific embodiment of the preceding form, the transparent substrate according to the invention is such that the geometric thickness of the insertion layer (Eᵢₙ) is such that, on the one hand, its ohmic thickness is at most equal to 10¹² ohms, preferably at most equal to 10⁷ ohms, more preferably at most equal to 10⁴ ohms, the ohmic thickness being equal to the ratio of, on the one hand, the resistivity of the material constituting the insertion layer (p) to, on the other hand, the geometric thickness of this same layer (1), and that, on the other hand, the geometric thickness of the insertion layer is linked to the geometric thickness of the first organic layer of the organic light-emitting device (E_{org}), the term first organic layer denoting all of the organic layers included between the insertion layer and the organic light-emitting layer, by the relationship: E_{org}=Eᵢₙ−A where A is a constant, the value of which is within the range extending from 5.0 to 75.0 nm, preferably from 20.0 to 60.0 nm, more preferably from 30.0 to 45.0 nm. The inventors have determined that, surprisingly, the relationship E_{org}=Eᵢₙ−A makes it possible to use the geometric thickness of the first organic layer of the organic light-emitting device to optimize the optical parameters (geometric thickness and refractive index) of the insertion layer and thus to optimize the amount of light transmitted while retaining a thickness of the insertion layer compatible with electrical properties making it possible to avoid high starting voltages, for a first brightness maximum.

According to another specific embodiment, the glass substrate according to the invention is such that the geometric thickness of the insertion layer (Eᵢₙ) is such that, on the one hand, its ohmic thickness is at most equal to 10¹² ohms, preferably at most equal to 10⁷ ohms, more preferably at most equal to 10⁴ ohms, the ohmic thickness being equal to the ratio of, on the one hand, the resistivity of the material constituting the insertion layer (p) to, on the other hand, the geometric thickness of this same layer (1), and that, on the other hand, the geometric thickness of the insertion layer is linked to the geometric thickness of the first organic layer of the organic light-emitting device (E_{org}), the term first organic layer denoting all of the organic layers included between the insertion layer and the organic light-emitting layer, by the relationship: E_{org}=Eᵢₙ−C where C is a constant, the value of which is within the range extending from 150.0 to 250.0 nm, preferably from 160.0 to 225.0 nm, more preferably from 75.0 to 205.0 nm. The inventors have determined that, surprisingly, the relationship E_{org}=Eᵢₙ−C makes it possible to use the geometric thickness of the first organic layer of the organic light-emitting device to optimize the optical parameters (geometric thickness and refractive index) of the insertion layer and thus to optimize the amount of light transmitted while retaining a thickness of the insertion layer compatible with electrical properties making it possible to avoid high starting voltages, for a second brightness maximum.

According to another specific embodiment of the glass substrate according to the invention, the conducting metal layer of the electrode comprises, on at least one of its faces, at least one sacrificial layer. Sacrificial layer is understood to mean a layer which may be entirely or partly oxidized or nitrided. This layer makes it possible to prevent a deterioration in the conducting metal layer, in particular by oxidation or nitridation. In addition, although it may be located between the conducting metal layer and the crystallization layer, the presence of this sacrificial layer is compatible with the action of a crystallization layer. When it is present, the sacrificial layer comprises at least one compound chosen from metals, nitrides, oxides and metal oxides which are substoichiometric in oxygen. Preferably, the metals, nitrides, oxides and metal oxides which are substoichiometric comprise at least one element selected from Ti, Zr, Hf, V, Nb, Ta, Cr, Mo, W, Mn, Fe, Co, Ni, Cu, Zn and Al. Preferably, the sacrificial layer comprises at least Ti, Zr, Ni, Zn or Al. Most preferably, the sacrificial layer comprises at least Ti, TiOₓ (with x≦2), NiCr, NiCrOₓ, TiZrOₓ (TiZrOₓ indicates a layer of titanium oxide comprising 50% by weight of zirconium oxide) or ZnAlOₓ (ZnAlOₓ indicates a layer of zinc oxide comprising from 2% to 5% by weight of aluminum oxide). According to a specific embodiment in accordance with the preceding one, the thickness of the sacrificial layer comprises a geometric thickness of at least 0.5 nm. The thickness of the sacrificial layer comprises a thickness of at most 6.0 nm. More preferably, the thickness is equal to 2.5 nm. According to a preferred embodiment, a sacrificial layer is deposited on the face of the conducting metal layer which is outermost with respect to the substrate.

According to another embodiment, the glass substrate according to the invention is such that it comprises at least one scattering layer, said scattering layer being located between the transparent electrode and the substrate. Such a layer is described in the published documents WO2009/017035, WO2009/116531, WO2010/084922, WO2010/084925, WO2011/046156, WO2011/046190 and the application PCT/JP2011/074358, all incorporated here by reference. Generally, this scattering layer exhibits a thickness of more than 5 μm and is not regarded as a coherent optical system.

According to another specific embodiment, the glass substrate according to the invention is such that it comprises at least one functional coating. Preferably, said functional coating is located on the face opposite the face on which the electrode is deposited. This coating comprises at least one coating selected from an antireflective layer or multilayer stack, a scattering layer, an antifogging or dirt-repelling layer, an optical filter, in particular a layer of titanium oxide, and a selective absorbent layer.

According to a preferred embodiment, the textured glass substrate according to the invention essentially exhibits the following structure:
Sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, and most preferably having a value within the range extending from 35° to 60°.
Coating for improving the transmittance of light:
   Layer for improving the transmittance of light made of TiO₂ (merged with the barrier layer)
   Crystallization layer made of ZnO or of ZnₓSn_{y}O_{z} (with x+y≧3 and z≦6).
Conducting metal layer made of Ag; the geometric thickness of the coating endowed with properties for improving the transmittance of the light and the geometric thickness of the conducting metal layer are connected by the relationship:

T_{ME}=T_{ME}_{_{—}}₀[B*sin(Π*T_{D1}/T_{D1}_{_{—}}₀)]/(n_{substrate})³
where T_{ME}_{_{—}}₀, B and T_{D1}_{_{—}}₀ are constants with T_{ME}_{_{—}}₀ having a value within the range extending from 10.0 to 25.0 nm, preferably from 10.0 to 23.0 nm, B having a value within the range extending from 10.0 to 16.5 and T_{D1}_{_{—}}₀ having a value within the range extending from 23.9*n_{D1} to 28.3*n_{D1} nm with n_{D1} representing the refractive index of the coating for improving the transmittance of the light at a wavelength of 550 nm, and n_{substrate} represents the refractive index of the glass constituting the substrate at a wavelength of 550 nm. Preferably, the constants T_{ME}_{_{—}}₀, B and T_{D1}_{_{—}}₀ are such that T_{ME}_{_{—}}₀ has a value within the range extending from 10.0 to 23.0 nm, preferably from 10.0 to 22.5 nm, most preferably from 11.5 to 22.5 nm, B has a value within the range extending from 11.5 to 15.0 and T_{D1}_{_{—}}₀ has a value within the range extending from 24.8*n_{D1} to 27.3*n_{D1} nm. More preferably, the constants T_{ME}_{_{—}}₀, B and T_{D1}_{_{—}}₀ are such that T_{ME}_{_{—}}₀ has a value within the range extending from 10.0 to 23.0 nm, preferably from 10.0 to 22.5 nm, most preferably from 11.5 to 22.5 nm, B has a value within the range extending from 12.0 to 15.0 and T_{D1}_{_{—}}₀ has a value within the range extending from 24.8*n_{D1} to 27.3*n_{D1} nm.
Sacrificial layer: geometric thickness 1.0-3.0 nm, made of Ti.
Insertion layer: geometric thickness 3.0-20.0 nm, made of ZnₓSn_{y}O_{z} (with x+y≧3 and z≦6).
Layer for rendering uniform: geometric thickness 0.5-3.0 nm, made of X, X nitride or X oxynitride, with the X: Ti, Zr, Hf, V, Nb, Ta, Ni, Pd, Cr, Mo, Al, Zn, Ni/Cr or Zn doped with Al.

According to a preferred embodiment, the textured glass substrate according to the invention essentially exhibits the following structure:
Sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 15° to 80°, preferably having a value within the range extending from 25° to 70°, and most preferably having a value within the range extending from 35° to 60°.
Coating for improving the transmittance of light:
   Layer for improving the transmittance of light made of TiO₂ (merged with the barrier layer)
   Crystallization layer made of ZnO or of ZnₓSn_{y}O_{z} (with x+y≧3 and z≦6);
the geometric thickness of the coating for improving the transmittance of light is at least equal to 50.0 nm, preferably at least equal to 60.0 nm, more preferably at least equal to 70.0 nm, and at most equal to 100 nm, preferably at most equal to 90.0 nm, more preferably at most equal to 80.0 nm,
Conducting metal layer made of Ag; the geometric thickness of the conducting metal layer is at least equal to 6.0 nm, preferably at least equal to 8.0 nm, more preferably at least equal to 10.0 nm, and at most equal to 22.0 nm, preferably at most equal to 20.0 nm, more preferably at most equal to 18.0 nm.
Sacrificial layer: geometric thickness 1.0-3.0 nm, made of Ti.
Insertion layer: geometric thickness 3.0-20.0 nm, made of ZnₓSn_{y}O_{z} (with x+y≧3 and z≦6).
Layer for rendering uniform: geometric thickness 0.5-3.0 nm, made of X, X nitride or X oxynitride, with the X: Ti, Zr, Hf, V, Nb, Ta, Ni, Pd, Cr, Mo, Al, Zn, Ni/Cr or Zn doped with Al.

According to a preferred embodiment, the textured glass substrate according to the invention essentially exhibits the following structure:
Sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, and most preferably having a value within the range extending from 35° to 60°.
Coating for improving the transmittance of light:
   Layer for improving the transmittance of light made of TiO₂ (merged with the barrier layer)
   Crystallization layer made of ZnO or of ZnₓSn_{y}O_{z} (with x+y≧3 and z≦6);
the geometric thickness of the coating for improving the transmittance of light is at least equal to 20.0 nm and at most equal to 40.0 nm.
Conducting metal layer made of Ag; the geometric thickness of the conducting metal layer is at least equal to 16.0 nm, preferably at least equal to 18.0 nm, preferably at least equal to 20.0 nm, and at most equal to 29.0 nm, preferably at most equal to 27.0 nm, more preferably at most equal to 25.0 nm.
Sacrificial layer: geometric thickness 1.0-3.0 nm, made of Ti.
Insertion layer: geometric thickness 3.0-20.0 nm, made of ZnₓSn_{y}O_{z} (with x+y≧3 and z≦6).
Layer for rendering uniform: geometric thickness 0.5-3.0 nm, made of X, X nitride or X oxynitride, with the X: Ti, Zr, Hf, V, Nb, Ta, Ni, Pd, Cr, Mo, Al, Zn, Ni/Cr or Zn doped with Al.

The embodiments of the textured glass substrate are not limited to the embodiments set out above but can also result from a combination of two or more of them.

Another subject matter of the present invention concerns the process for the manufacture of the textured glass substrate comprising a transparent electrode. The process for the manufacture of the textured substrate according to the invention is a process according to which the layer for rendering uniform and/or a set of layers making up the electrode are deposited on the chemically pretextured glass substrate. Examples of such processes are cathode sputtering techniques, optionally assisted by a magnetic field, deposition techniques using a plasma or deposition techniques of CVD (Chemical Vapor Deposition) and/or PVD (Physical Vapor Deposition) type. Preferably, the deposition process is carried out under vacuum. The term “under vacuum” denotes a pressure of less than or equal to 1.2 Pa. More preferably, the process under vacuum is a magnetron sputtering technique. The process for the manufacture of the textured glass substrate comprises the continuous processes in which any layer constituting the electrode is deposited immediately following the layer which underlies it in the multilayer stack (for example: deposition of the stack constituting the electrode according to the invention on a substrate which is an advancing strip or else deposition of the stack on a substrate which is a panel). The manufacturing process also comprises the batchwise processes in which a period of time (for example, in the form of storage) separates the deposition of a layer and of the layer which underlies it in the stack constituting the electrode.

According to a preferred embodiment, the process for the manufacture of the textured substrate according to the invention is such that it is carried out in three steps broken down in the following way:
texturing of a face of the glass substrate by acidic attack using an aqueous solution based on hydrofluoric acid having a pH ranging from 0 to 5, said acidic attack being carried out in at least one stage, the attack time being between 10 s and 30 minutes,
deposition on the chemically pretextured glass substrate of the coating endowed with properties for improving the transmittance of light on the face of the substrate opposite the textured face,
deposition of the conducting metal layer, directly followed by the deposition of the various functional elements constituting the optoelectronic system, on the face of the substrate opposite the textured face.

According to another preferred embodiment, the process for the manufacture of the textured glass substrate according to the invention is such that it is carried out in three steps broken down in the following way:
texturing of a face of the glass substrate by acidic attack using an aqueous solution based on hydrofluoric acid having a pH ranging from 0 to 5, said acidic attack being carried out in at least one stage, the attack time being between 10 s and 30 minutes,
deposition on the chemically pretextured glass substrate of the coating endowed with properties for improving the transmittance of light through the electrode, of the conducting metal layer, of the sacrificial layer, of the insertion layer, on the face of the substrate opposite the textured face,
deposition of the layer for rendering uniform, directly followed by the deposition of the various functional elements constituting the optoelectronic system, on the face of the substrate opposite the textured face.

When the layer for rendering uniform or the conducting metal layer are deposited subsequently, the organic part of the optoelectronic device is deposited immediately after the deposition of the layer for rendering uniform or of the conducting metal layer, that is to say without exposing the layer for rendering uniform or the conducting metal layer to the air before the deposition of the organic part of the optoelectronic device. The advantage offered by these processes is that they make it possible to avoid oxidation of the conducting layer or layer for rendering uniform when these are composed of metal. According to a specific form of the preceding form, the barrier layer is deposited (for example: by CVD) on a glass strip. The following layers of the stack, with or without the layer for rendering uniform, are deposited under vacuum on said strip or on glass panels cut out from said strip. The panels covered with the barrier layer which are obtained after being cut out are optionally stored.

According to a specific embodiment, the layer for rendering uniform the surface electrical properties based on oxides and/or oxynitrides can be obtained by direct deposition. According to an alternative form, the layer for rendering uniform based on oxides and/or oxynitrides can be obtained by oxidation of the corresponding metals and/or nitrides (for example: Ti is oxidized to give Ti oxide, Ti nitride is oxidized to give Ti oxynitride). This oxidation can take place directly or a long time after the deposition of the layer for rendering uniform. The oxidation can be natural (for example: an interaction with an oxidizing compound present during the process for the manufacture or during the storage of the electrode before complete manufacture of the optoelectronic device) or can result from a post treatment (for example: a treatment with ozone under ultraviolet radiation).

According to an alternative embodiment, the process comprises an additional stage of structuring the surface of the electrode. The structuring of the surface of the electrode is different from the texturing of the substrate. This additional stage carries out a modeling of the surface and/or an ornamentation of the surface of the electrode. The process of modeling the surface of the electrode comprises at least etching by laser or by chemical attack. The process of ornamentation of the surface comprises at least masking. Masking is the operation by which a portion at least of the surface of the electrode is covered with a protective coating for the purpose of a post treatment, for example a chemical attack on the uncovered portions.

According to another subject matter of the invention, the glass substrate according to the present invention is incorporated in a light-emitting or light-collecting optoelectronic device. According to a preferred embodiment, the optoelectronic device is an organic light-emitting device comprising at least one textured glass substrate in accordance with the invention described above.

According to an alternative form of the above embodiment, the organic light-emitting device comprises, above the substrate according to the invention, an OLED system provided for emitting a quasiwhite light. Several methods are possible in order to produce a quasiwhite light: by mixing, within just one organic layer, compounds which emit red, green and blue light, by stacking three structures of organic layers respectively corresponding to the parts emitting red, green and blue light or two structures of organic layers (yellow and blue emission), or by juxtaposing three (red, green and blue emission) or two (yellow and blue emission) structures of organic layers, in combination with a system for scattering the light.

The term quasiwhite light is intended to denote a light, the chromatic coordinates at 0° of which, for radiation perpendicular to the surface of the substrate, are included in one of the eight chromaticity quadrangles, contours of the quadrangles included. These quadrangles are defined on pages 10 to 12 of the standard ANSI NEMA ANSLG c78.377-2008. These quadrangles are represented in figure Al, PART 1, entitled “Graphical representation of the chromaticity specification of SSL products in Table 1, on the CIE (X,Y) chromaticity diagram”.

According to a specific embodiment, the organic light-emitting device is incorporated in a glazing, a double glazing or a laminated glazing. It is also possible to incorporate several organic light-emitting devices, preferably a large number of organic light-emitting devices.

According to another specific embodiment, the organic light-emitting device is enclosed in at least one encapsulating material made of glass and/or of plastic. The various embodiments of the organic light-emitting devices can be combined.

Finally, the different organic light-emitting devices have a vast range of use. The invention applies in particular to the possible uses of these organic light-emitting devices in producing one or more luminous surfaces. The term luminous surface comprises, for example, illuminating tiles, luminous panels, luminous partitions, worktops, greenhouses, flashlights, screen backgrounds, drawer bottoms, luminous roofs, touchscreens, lamps, photographic flash bulbs, luminous display backgrounds, safety signals or racks.

The textured glass substrate in accordance with the invention will now be illustrated using the following figures. The figures exhibit, in a nonlimiting way, a number of structures of substrates, more particularly of structures of stacks of layers constituting the electrode included in the substrate according to the invention. These figures are purely illustrative and do not constitute a presentation of the scale of the structures. In addition, the performances of the organic light-emitting devices comprising the textured glass substrate according to the invention will also be presented in the form of figures.

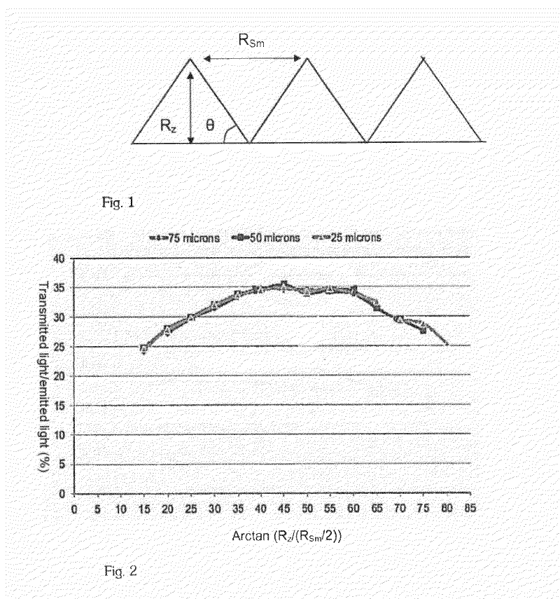

FIG. 1: Diagrammatic representation of the structure of the texturing.

FIG. 2: Change in the transmitted light/emitted light ratio as a function of arctan(R_{z}/(R_{Sm}/2)) for pyramid base widths of 25, 50 and 75 μm.

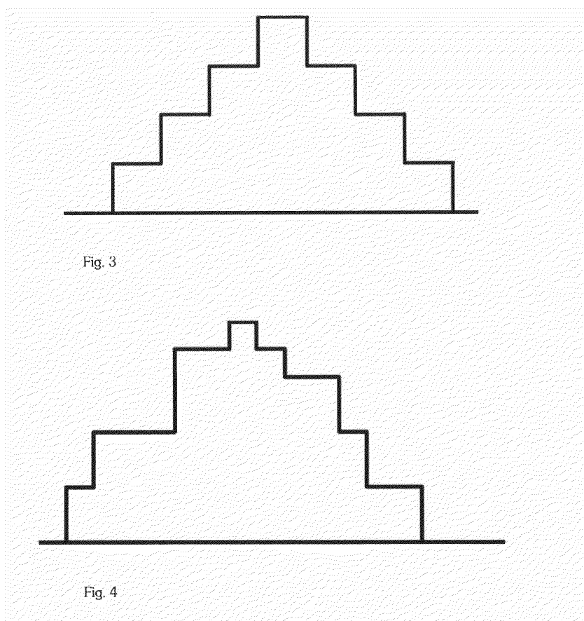

FIG. 3: Example of texturing patterns in the form of a step pyramid.

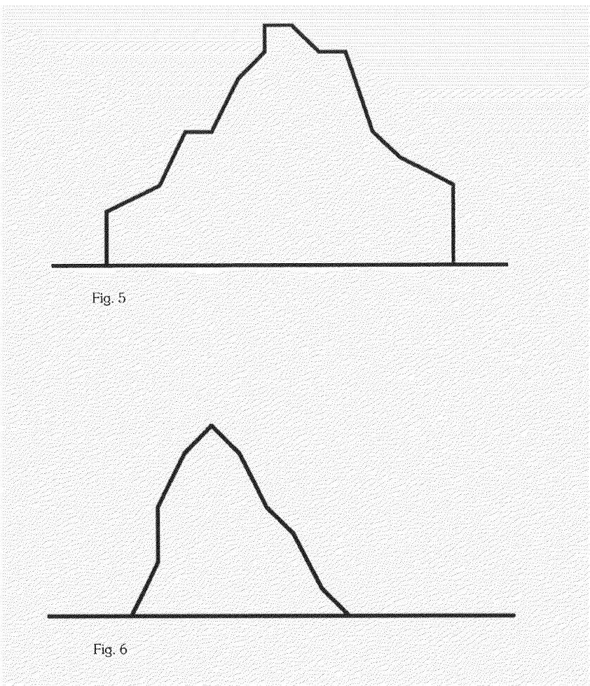

FIG. 4: Example of texturing patterns in the form of a step pyramid.

FIG. 5: Example of texturing patterns in the form of a step pyramid.

FIG. 6: Example of texturing patterns in the form of a step pyramid.

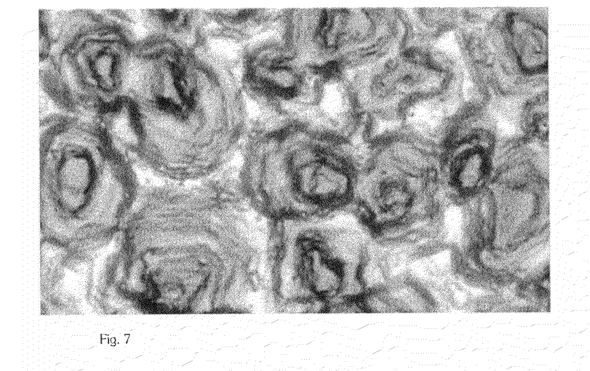

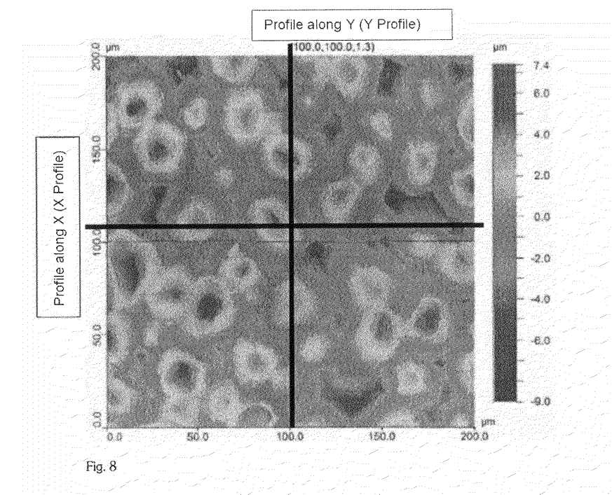

FIG. 7: Electron micrograph of a textured glass substrate according to the invention.

FIG. 8: Diagrammatic representation of the experimental device which makes it possible to determine the change in the electroluminescence, in the dominant wavelength and in the color purity as a function of the angle of observation.

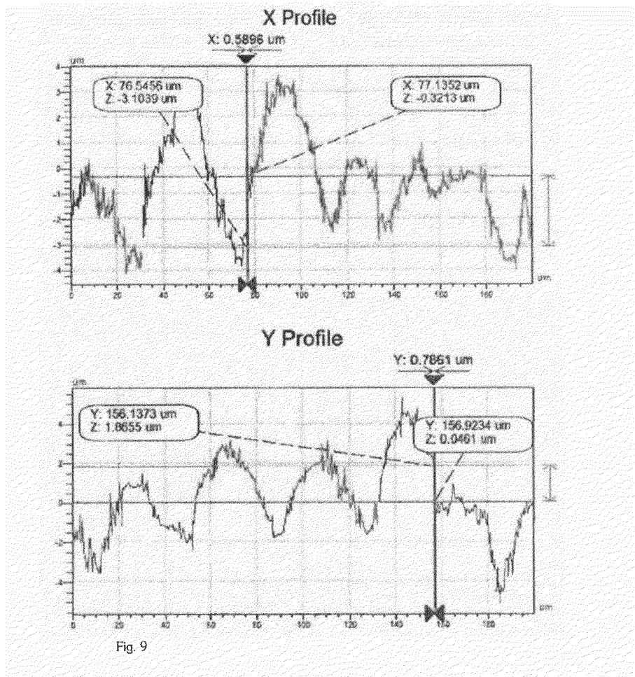

FIG. 9: Change in the dominant wavelength and in the color purity as a function of the angle of observation.

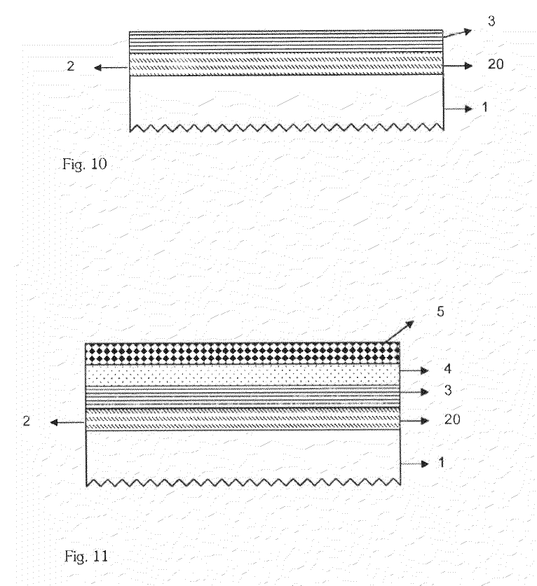

FIG. 10: Cross section of a textured glass substrate according to the invention according to a preferred embodiment.

FIG. 11: Cross section of a textured glass substrate comprising, at the transparent electrode, a minimum number of layers.

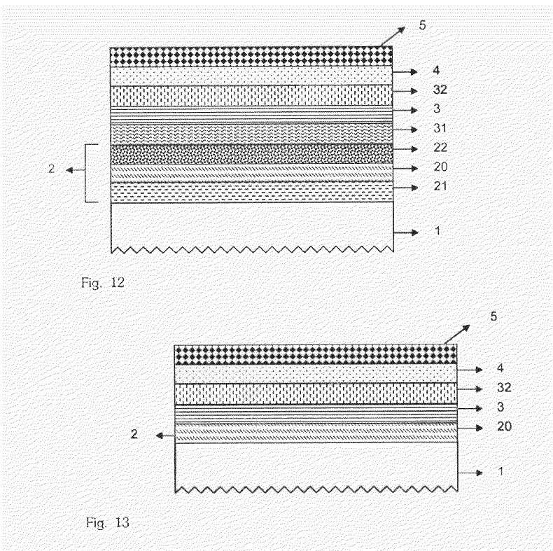

FIG. 12: Cross section of a textured glass substrate according to the invention according to a second embodiment.

FIG. 13: Cross section of a textured glass substrate comprising, at the transparent electrode, a minimum number of layers having a different effect.

FIG. 14: Change in the brightness of an organic light-emitting device emitting a quasiwhite light and comprising a support having a refractive index at 1.4 at a wavelength equal to 550 nm as a function of the geometric thickness of the coating for improving the transmittance of the light, having a refractive index of 2.3 at a wavelength of 550 nm, and of the geometric thickness of a conducting metal layer made of Ag.

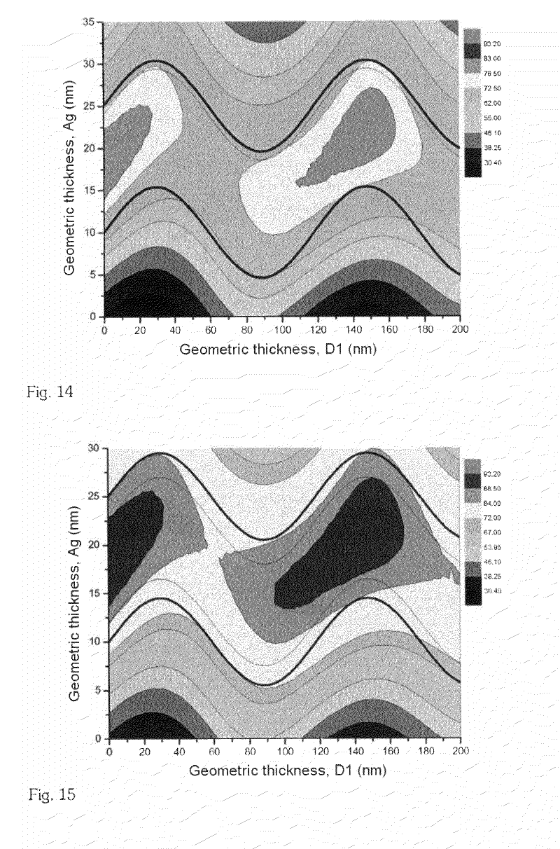

FIG. 15: Change in the brightness of an organic light-emitting device emitting a quasiwhite light and comprising a support having a refractive index at 1.5 at a wavelength equal to 550 nm as a function of the geometric thickness of the coating for improving the transmittance of the light, having a refractive index of 2.3 at a wavelength of 550 nm, and of the geometric thickness of a conducting metal layer made of Ag.

FIG. 16: Change in the brightness of an organic light-emitting device emitting a quasiwhite light and comprising a support having a refractive index at 1.6 at a wavelength equal to 550 nm as a function of the geometric thickness of the coating for improving the transmittance of the light, having a refractive index of 2.3 at a wavelength of 550 nm, and of the geometric thickness of a conducting metal layer made of Ag.

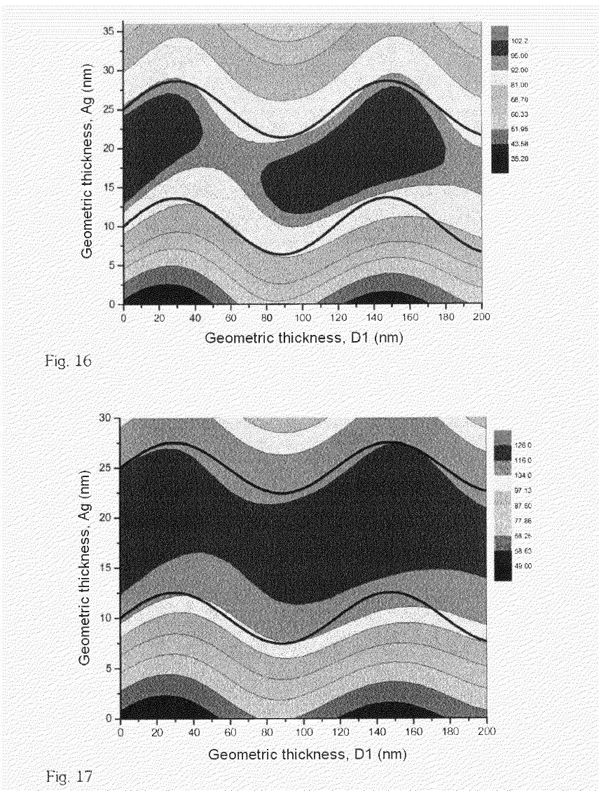

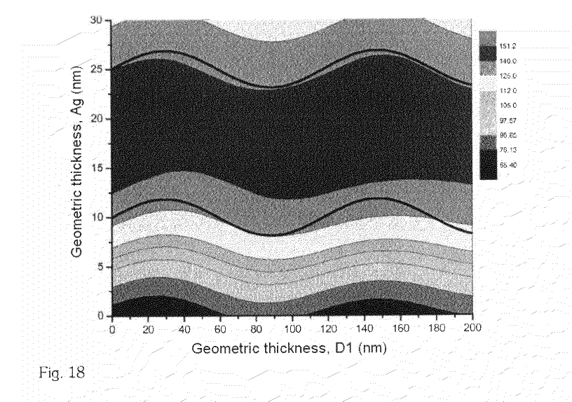

FIG. 17: Change in the brightness of an organic light-emitting device emitting a quasiwhite light and comprising a support having a refractive index at 1.8 at a wavelength equal to 550 nm as a function of the geometric thickness of the coating for improving the transmittance of the light, having a refractive index of 2.3 at a wavelength of 550 nm, and of the geometric thickness of a conducting metal layer made of Ag.

FIG. 18: Change in the brightness of an organic light-emitting device emitting a quasiwhite light and comprising a support having a refractive index equal to 2.0 at a wavelength equal to 550 nm as a function of the geometric thickness of the coating for improving the transmittance of the light, having a refractive index of 2.3 at a wavelength of 550 nm, and of the thickness.

FIG. 1 diagrammatically represents the structure of the texturing of a glass substrate having improved properties for optoelectronic devices. The texturing of the glass substrate is defined by the parameters R_{z}, R_{Sm} and θ. R_{z} represents the mean height of the patterns and R_{Sm} is the mean distance separating the summits of two contiguous patterns. The angle θ is defined by the relationship:

θ=arctan(R_{z}/(R_{Sm}/2))

FIG. 2 represents the change in the percentage of green light (λ: 550 nm) which exits frontally (perpendicularly with respect to the mean plane of the surface of the substrate) from an organic light-emitting device comprising a texturing of the surface according to the invention with respect to the light emitted by this device when a current of 1 mA is applied. Surprisingly, these calculations show that the amount of light transmitted is a function of the angle θ. When the surface is devoid of texturing, the emitted light/transmitted light ratio is 12.5%. It is observed that, when the angle θ is between 15° and 80°, the emitted light/transmitted light ratio is a minimum of 25%, which corresponds to an increase by a factor 2 in the brightness, viewed frontally, of the organic light-emitting device. When the angle θ is between 25° and 70°, the emitted light/transmitted light ratio is a minimum of 30%, which corresponds to an increase by a factor 2.4 in the brightness, viewed frontally, of the organic light-emitting device. Finally, when the angle θ is between 35° and 60°, the emitted light/transmitted light ratio is a minimum of 34%, which corresponds to an increase by a factor 2.7 in the brightness, viewed frontally, of the organic light-emitting device. The simulations thus show that an appropriate texturing of the surface makes it possible to obtain an increase in the amount of light transmitted and thus an increase in the frontal brightness, in other words in the light power of the source. Appropriate texturing is understood to mean a value of the angle θ of between 15° and 80°, preferably between 25° and 70°, more preferably between 35° and 60°. These simulations were carried out by considering a texturing based on geometric patterns of pyramid type having a square base. The simulation was calculated using the “Light Tool-version 6” program from Optical Research Associates. These simulations were calculated by considering a model in which an emitter emitting at 1 mA is introduced in the middle of the organic part of the organic light-emitting device. The light emitted is polychromatic radiation, the dominant wavelength of which lies in the region of green-colored light. The structure of the model considered is as follows:
a substrate made of textured clear glass according to the invention
a transparent electrode comprising ITO
a layer made of N,N′-bis(1-naphthyl)-N,N′-diphenyl-1,1′-biphenyl-4,4′-diamine, abbreviated to alpha-NPD,
a layer made of tris(8-hydroxyquinoline)aluminum(III)
a layer made of LiF,
an upper reflecting electrode made of Al.

According to the simulations carried out, no influence of the size of the base of the pyramid was observed; only the angle θ had a significant impact. Furthermore, the simulations showed that joined pyramids are preferable. This is because the more distant the pyramids are from one another, the weaker the effect of the texturing on the amount of light transmitted. The geometric patterns must thus be as close as possible to one another; these patterns are preferably joined patterns, most preferably completely joined patterns. The term joined patterns defines two patterns which touch in at least a portion of their base. Completely joined pattern is understood to mean that every side of the base of a pattern also forms part of the base of another pattern.

The inventors have determined that a surface texturing which makes it possible to obtain geometric patterns such that the arctangent of (R_{z}/(R_{Sm}/2)) corresponds to a value of the angle θ of between 15° and 80°, preferably between 25° and 70°, more preferably between 35° and 60°, can be produced by chemical attack. Chemical attack can be carried out using concentrated alkaline solutions or acid solutions. The alkaline solutions are used at high concentrations and are applied to the glass substrate having a temperature of at least 350° or brought after application to at least this temperature.

The chemical attack on the substrate can advantageously be carried out by a controlled acidic attack, using acid solutions commonly used in the manufacture of textured glass (for example by attack using hydrofluoric acid). Generally, the acid solutions are aqueous hydrofluoric acid solutions having a pH ranging from 0 to 5. Such aqueous solutions can comprise, in addition to the hydrofluoric acid, salts of this acid, other acids, such as, for example, hydrochloric acid, sulfuric acid, nitric acid, phosphoric acid and their salts (for example: Na₂SO₄, K₂SO₄, (NH₄)₂SO₄, BaSO₄, and the like), and optional additives in minor proportions (for example: acid/base buffering agents, wetting agents, and the like). The alkali metal salts and the ammonium salts are generally preferred; mention may very particularly be made, among these, of sodium, potassium and ammonium hydrofluoride and/or ammonium bifluoride. Such solutions are, for example, aqueous solutions comprising from 0 to 600 g/l of hydrofluoric acid, preferably from 150 to 250 g/l of hydrofluoric acid, and also comprising from 0 to 700 g/l of NH₄HF₂, preferably from 150 to 300 g/l of NH₄HF₂. The acidic attack can be carried out in one or more stages. The attack times are at least 10 s. Preferably, the attack times are at least 20 seconds. The attack times do not exceed 30 minutes. This chemical attack makes it possible to obtain a substrate such that the geometric patterns comprise at least one structure of step pyramid type having a polygonal base. The term “step pyramid” is understood to mean a pyramid, at least one face of which exhibits a staircase structure. This staircase structure is such that the dimensions of the steps and of the risers are not necessarily equal to one another and paired. The angle formed by a plane comprising a step and a plane comprising a riser is not necessarily equal to 90°. Preferably, the “step-riser” angle seen from the inside of the pyramid is at least 100°, more preferably at least 120°. This angle can vary from one “step-riser” structure to another. Such types of structure are presented in FIGS. 3, 4, 5 and 6. FIG. 7 exhibits an electron micrograph of a substrate according to the invention obtained using acid texturing, the geometric patterns of which are patterns of “step pyramid” type and the texturing of which, described in terms of roughness measurements, is R_{z}: 14 μm. FIG. 8 shows a 3D image obtained by interferometric microscopy. Two linear profiles, one along X and one along Y, taken randomly from the 3D image of the sample (without necessarily passing through the summits of the profiles) in order to determine the mean distance between the profiles (RmS) are represented in FIG. 9. Over a distance of 200 microns, it is easily possible to count between six and seven profiles, both in a horizontal direction (along X) and in a vertical direction (along Y). It is thus possible to determine RmS as a value of between 28 microns (seven profiles) and 34 microns (six profiles). The mean angle of the profiles is thus between 39° and 45°.

The roughness measurements were carried out using a Veeco 3D interferometer device. The samples were measured using the following parameters:

### Size: 2036×2036

### Sampling: 98.21 nm

### Mode: VSI

Terms removed: Tilt

### Filtering: None

The organic light-emitting device (1) used is composed of the following stack, starting from the emitting surface:
clear glass with a thickness of 4 mm,
a transparent electrode comprising:
Optical optimization coating comprising an optical optimization layer made of TiO₂ of 60 nm and a crystallization layer formed of ZnₓSn_{y}O_{z} (with x+y≧3 and z≦6) (merged with the barrier layer with a thickness of 9.0 nm)
Conducting layer made of Ag: geometric thickness 14.6 nm
Sacrificial layer made of Ti: geometric thickness 6.0 nm
Insertion layer: ZnₓSn_{y}O_{z} (with x+y≧3 and z≦6): geometric thickness 9.0 nm
Layer for rendering uniform made of TiN with a geometric thickness of 1.5 nm
A set of organic layers and a counterelectrode made of silver as described in the part titled “Methods Summary”, of the paper by S. Reineke et al., published in Nature, vol. 459, pp. 234-238, 2009.

FIG. 10 represents an example of a textured glass substrate according to the invention, this substrate comprising a transparent electrode. The general structure of the glass substrate according to the invention is as follows:
A sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, and most preferably having a value within the range extending from 35° to 60° (1).
An optical optimization coating (2) comprising an optical optimization layer (20).
A conducting metal layer (3).

FIG. 11 represents an alternative example of a glass substrate according to the invention, this substrate comprising a transparent electrode. The general structure of the glass substrate according to the invention is as follows:
A sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, and most preferably having a value within the range extending from 35° to 60° (1).
An optical optimization coating (2) comprising an optical optimization layer (21).
A conducting layer (3).
An insertion layer (4).
A layer for rendering uniform (5).

FIG. 12 represents another alternative example of a glass substrate according to the invention, this substrate comprising a transparent electrode. The general structure of the glass substrate according to the invention is as follows:
A sheet of clear or extra clear glass textured by chemical attack, completely or partially on at least one of its faces, by a set of geometric patterns such that the arctangent of the ratio of the mean height of the patterns, R_{z}, to half the mean distance separating the summits of two contiguous patterns, R_{Sm}, is equal to a value within the range extending from 35° to 80°, preferably having a value within the range extending from 35° to 70°, and most preferably having a value within the range extending from 35° to 60° (1).
An optical optimization coating (2) comprising:
   A barrier layer (20).
   An optical optimization layer (21).
   A crystallization layer (22).
A sacrificial layer (31).
A conducting layer (3).
A sacrificial layer (32).
An insertion layer (4).
A layer for rendering uniform (5).

FIG. 13 represents another alternative example of a substrate according to the invention, this substrate comprising a transparent electrode. The general structure of the stack, starting from the substrate according to the invention (1), is as follows:
An optical optimization coating (2) comprising an optical optimization layer (21).
A conducting layer (3).
A sacrificial layer (32).
An insertion layer (4).
A layer for rendering uniform (5).

FIGS. 14, 15, 16, 17 and 18 represent the change in the brightness of an organic light-emitting device emitting a quasiwhite light as a function of the geometric thickness of the coating for improving the transmittance of the light (D1), having a refractive index of 2.3 (n_{D1}) at a wavelength of 550 nm, and of the geometric thickness of a conducting metal layer made of Ag, and comprising a support respectively having a refractive index equal to 1.4, 1.5, 1.6, 1.8 and 2.0 at a wavelength equal to 550 nm. The structure of the organic light-emitting device comprises the following stack:
Sheet of untextured clear glass having a geometric thickness equal to 1000.0 nm.
Electrode
   Coating for improving the transmittance of light.
   Conducting metal layer made of Ag.
The organic part of the organic light-emitting device is such that it exhibits the following structure:
   a hole transporting layer (HTL) having a geometric thickness equal to 25.0 nm,
   an electron blocking layer (EBL) having a geometric thickness equal to 10.0 nm,
   an emissive layer, emitting a Gaussian spectrum of white light corresponding to the illuminant A and having a geometric thickness equal to 16.0 nm,
   a hole blocking layer (HBL) having a geometric thickness equal to 10.0 nm,
   an electron transporting layer (ETL) having a geometric thickness equal to 43.0 nm.
A counterelectrode made of Al having a thickness equal to 100.0 nm.

Surprisingly, these calculations show that a maximum brightness is obtained for a transparent substrate such that the optical thickness of the coating endowed with properties for improving the transmittance of the light (110), T_{D1}, and the geometric thickness of the conducting metal layer (112), T_{ME}, are connected by the relationship:

T_{ME}=T_{ME}_{_{—}}₀[B*sin(Π*T_{D1}/T_{D1}_{_{—}}₀)]/(n_{substrate})³

where T_{ME}_{_{—}}₀, B and T_{D1}_{_{—}}₀ are constants with T_{ME}_{_{—}}₀ having a value within the range extending from 10.0 to 25.0 nm, B having a value within the range extending from 10.0 to 16.5 and T_{D1}_{_{—}}₀ having a value within the range extending from 23.9*n_{D1} to 28.3*n_{D1} nm with n_{D1} representing the refractive index of the coating for improving the transmittance of the light at a wavelength of 550 nm, and n_{substrate} represents the refractive index of the glass constituting the substrate at a wavelength of 550 nm. The brightness was calculated using the SETFOS version 3 (Semiconducting Emissive Thin Film Optics Simulator) program from Fluxim. This brightness is expressed in an arbitrary unit. The sinewaves appearing in the form of thicker lines mark the extreme values of the range selected by the equation T_{ME}=T_{ME}_{_{—}}₀+[B*sin (Π*T_{D1}/T_{D1}_{_{—}}₀)]/(n_{substrate})³. The inventors have determined that, surprisingly, the range selected is not only valid for an organic device emitting quasiwhite light but also any color type emitted (for example: red, green, blue). The inventors have determined that, with the same transparent substrate structure, the use of a glass substrate, the glass of which has a higher refractive index, makes it possible to increase the amount of light transmitted by the optoelectronic system. Higher refractive index is understood to mean a refractive index at least equal to 1.4, preferably at least equal to 1.5, more preferably at least equal to 1.6, most preferably at least equal to 1.7. Specifically, as is shown by the comparison of FIGS. 5 and 9, an increase of the order of 180% in the brightness of the OLED device is observed when, with the same transparent substrate structure, use is made of a support having a refractive index equal to 2.0 instead of a support with a refractive index equal to 1.4, the refractive index of the glass being the refractive index at a wavelength of 550 nm. Furthermore, the inventors have determined that, surprisingly, the relationship between the optical thickness of the coating endowed with properties for improving the transmittance of the light (2), T_{D1}, and the geometric thickness of the conducting metal layer (3), T_{ME}, also applies to the textured glass substrate according to the invention.

The effect of the roughness of the support on the light-extraction effectiveness or out-coupling coefficient efficiency (OCE) is presented in table I.

TABLE I

| R_{z} (μm) | R_{Sm} (μm) | OCE |
|---|---|---|
| 14 | 28-34 | 1.41 |

The OCE is a factor which defines the amount of light which can be extracted in comparison with a reference. The reference used is an OLED device of identical structure (anode, organic part of the OLED and cathode) but the glass sheet of which is not textured. The OCEs are measured on OLED devices exhibiting the following structure:
Textured sheet of extra clear glass having a geometric thickness equal to 4 mm
A transparent electrode comprising:
Optical optimization coating comprising an optical optimization layer made of TiO₂ of 60 nm and a crystallization layer formed of ZnₓSn_{y}O_{z} (with x+y≧3 and z≦6) (merged with the barrier layer with a thickness of 9.0 nm)
Conducting layer made of Ag: geometric thickness 14.6 nm
Sacrificial layer made of Ti: geometric thickness 6.0 nm
Insertion layer: Zn—Sn_{y}O_{z} (with x+y≧3 and z≦6): geometric thickness 9.0 nm
Layer for rendering uniform made of TiN with a geometric thickness of 1.5 nm
A set of organic layers and a counterelectrode made of aluminum as described in the part titled

“Methods Summary”, of the paper by S. Reineke et al., published in Nature, vol. 459, pp. 234-238, 2009.

The OCE values were obtained in the following way:
Absolute measurement of the light flux with the Labsphere LMS-200 integrating sphere. The voltage applied to each sample is that required in order to obtain a current strength of 4 mA.
The OCE is obtained by dividing the value of the light flux obtained by the value of the light flux measured for the reference.

The angular dependence of the colorimetric coordinates in the CIE (x,y) diagram for a reference OLED device, said reference sample being identical to that used to determine the OCE values presented in table I, and a device of identical structure (anode, organic part of the OLED and cathode), the glass sheet of which exhibits a roughness R_{z} of 14 μm and an R_{Sm} of 28-34 μm, is presented in table II. It is observed that a reduced angular dependence of the colorimetric coordinates is obtained with a textured glass sheet. Δx^{0°-80°} represents the difference between the highest value of x measured between 0° and 80° and the lowest value of x measured between 0° and 80°. Likewise, Δx^{0°-80°} represents the difference between the highest value of y measured between 0° and 80° and the lowest value of y measured between 0° and 80°.

TABLE II

| Sample | Δx^{0°-80°} | Δy^{0°-80°} |
|---|---|---|
| Untextured glass sheet | 0.26 | 0.25 |
| Textured glass sheet | 0.14 | 0.16 |
| having an R_{z} of 14 μm and | | |
| an R_{Sm} of 28-34 μm | | |

The optical measurements were carried out using a multichannel spectroscope having the trade name C10027 sold by Hamamatsu Photonics K.K. The measurement angle is defined by the angle formed between the perpendicular to the glass sheet, on the one hand, and the straight line perpendicular to the measurement surface of the spectroscope, on the other hand.

1. A glass substrate, comprising
a transparent electrode on one face of the substrate,
wherein the substrate is textured, completely or partially, on a face of the substrate opposite to the face on which the transparent electrode is deposited, by a set of geometric patterns such that an arctangent of a ratio of a mean height of the patterns, R_{z}, to half the mean distance separating summits of two contiguous patterns, R_{Sm}, is at least equal to an angle of 35° and at most equal to an angle of 80°.

2. The glass substrate of claim 1, which has a refractive index of at least 1.5.

3. The glass substrate of claim 1, wherein the geometric patterns comprise a structure of “step pyramid” having a polygonal base.

4. The glass substrate of claim 1, further comprising: joined patterns.

5. The class substrate of claim 1, wherein the transparent electrode comprises a stack comprising
a conducting metal layer, and
a coating endowed with properties for improving transmittance of light through the transparent electrode,
the coating has a geometric thickness of greater than 3.0 nm and at most 200 nm,
the coating comprises a layer for improving the transmittance of light, and
the coating is located between the conducting metal layer and the face of the substrate on which the transparent electrode is deposited.

6. The glass substrate of claim 5, wherein
the stack comprises just one conducting metal layer, and
an optical thickness of the coating, T_{D1}, and a geometric thickness of the conducting metal layer, T_{ME}, satisfies the relationship:
T_{ME}=T_{ME}_{_{—}}₀[B*sin(Π*T_{D1}/T_{D1}_{_{—}}₀)]/(n_{substrate})³
where
T_{ME}_{_{—}}₀ is a constant of from 10.0 to 25.0 nm,
B is a constant of from 10.0 to 16.5,
T_{D1}_{_{—}}₀ is a constant of from 23.9*n_{D1} to 28.3*n_{D1} nm with n_{D1} representing refractive index of the coating for improving the transmittance of the light at a wavelength of 550 nm, and
n_{substrate} is the refractive index of the glass constituting the substrate at a wavelength of 550 nm.

7. The glass substrate of claim 5, wherein the coating comprises an additional crystallization layer, which, with respect to the face of the substrate on which the electrode is deposited, is the outermost layer of the stack.

8. The glass substrate of claim 5, wherein the coating comprises an additional barrier layer.

9. The glass substrate of claim 5, wherein the electrode comprises a thin layer for rendering uniform the surface electrical properties located at the summit of the stack, with respect to the face of the substrate on which the electrode is deposited.

10. The glass substrate of claim 9, wherein the transparent electrode comprises an additional insertion layer located between the conducting layer and the thin layer.

11. The glass substrate of claim 10, wherein the conducting metal layer comprises, on at least one face, a sacrificial layer.

12. A process for manufacturing the glass substrate of claim 5, the process comprising:
texturing a face of the glass substrate by acidic attack using an aqueous solution based on hydrofluoric acid having a pH ranging from 0 to 5, thereby obtaining a chemically pretextured glass substrate with a textured face,
depositing the coating on a face of the chemically pretextured glass substrate opposite the textured face,
depositing the conducting metal layer on the face of the glass substrate opposite the textured face, directly followed by deposition of various functional elements of an optoelectronic system comprising the glass substrate,
wherein the acidic attack is carried out in at least one stage for a period of from 10 seconds to 30 minutes.

13. A process for manufacturing the glass substrate of claim 11, the process comprising:
texturing a face of the glass substrate by acidic attack using an aqueous solution based on hydrofluoric acid having a pH ranging from 0 to 5, thereby obtaining a chemically pretextured glass substrate with a textured face,
depositing the coating, the conducting metal layer, the sacrificial layer, and the insertion layer, on a face of the chemically pretextured glass substrate opposite the textured face,
depositing the thin layer on the face of the substrate opposite the textured face, directly followed by deposition of various functional elements of an optoelectronic system comprising the glass substrate,
wherein the acidic attack is carried out in at least one stage for a period of from 10 seconds to 30 minutes.
